(19) United States
(12) Patent Application Publication
(10) Pub. No.: US 2019/0157358 A1
(43) Pub. Date: May 23, 2019

(54) ORGANIC ELECTROLUMINESCENCE DISPLAY DEVICE

(71) Applicant: Japan Display Inc., Minato-ku (JP)

(72) Inventor: Norihisa MAEDA, Minato-ku (JP)

(73) Assignee: Japan Display Inc., Minato-ku (JP)

(21) Appl. No.: 16/194,987

(22) Filed: Nov. 19, 2018

(30) Foreign Application Priority Data
Nov. 21, 2017 (JP) 2017-223965

(51) Int. Cl. H01L 27/32; H01L 51/52; H01L 51/00

(52) U.S. Cl. CPC H01L 27/3211; H01L 51/5221; H01L 51/5275; H01L 51/5088; H01L 51/5206; H01L 51/0081; H01L 27/3244; H01L 51/5265

(57) ABSTRACT

There is provided an organic EL display device having a first subpixel region and a second subpixel region. The organic EL display device includes a first light emission film, a second light emission film, an upper electrode, a cap layer configured to include a high refractive index film, a middle refractive index film, and a low refractive index film whose refractive indices are different from one another on an upper layer side of the upper electrode, and the low refractive index film is disposed to be distant from the substrate more than the other films included in the cap layer are, in the first and second subpixel regions. The middle refractive index film of the first subpixel region is formed to be thicker than the middle refractive index film of the second subpixel region.

### CROSS-REFERENCE TO RELATED APPLICATION

The present application claims priority from the Japanese Application JP2017-223965 filed on Nov. 21, 2017, the content of which is hereby incorporated by reference into this application.

### BACKGROUND OF THE INVENTION

### 1. Field of the Invention

One or more embodiments of the present invention relate to an organic EL display device.

### 2. Description of the Related Art

Recent years, an organic EL display device which uses an organic EL element has been put into a practical use. There is a case where a cap layer is provided in an organic EL display device in order to improve an efficiency of extracting light emitted by an organic EL element. For example, Japanese Patent Application Laid-Open No. 2017-004980 discloses providing a cap layer of different thickness for each pixel which emits light of different wavelength.

Further, Japanese Patent Application Laid-Open No. 2015-099773 discloses a configuration where a cap layer is constituted by two different types of layers having different refractive indices, and thickness of a cap layer having a high refractive index is different at each subpixel, for improving the efficiency of extracting light. By this configuration, light emitted by an organic EL element is reflected at an interface of the two different kinds of layers, and thus a so-called microcavity structure is formed.

### SUMMARY OF THE INVENTION

In order to form the microcavity structure, it is necessary to adjust an optical path length in accordance with a wavelength of light, by changing the thickness of the cap layer. Therefore, in the case light is emitted whose wavelength varies on a subpixel-by-subpixel basis, it is necessary to adjust the thickness of the cap layer for each subpixel.

However, in Japanese Patent Application Laid-Open No. 2015-099773, an optical path length is adjusted by changing thickness of a cap layer whose refractive index is high. In this case, the optical path length largely changes according to a slight change of the thickness of the cap layer, and thus it is difficult to adjust the optical path length.

The present invention has been made in view of the problems as described above, and the object thereof is to provide an organic EL display device having a microcavity structure with which an optical wave length can be easily adjusted.

According to one aspect of the present invention, there is provided an organic EL display device having a first subpixel region and a second subpixel region, including a substrate, a first light emission film which is disposed on the substrate of the first subpixel region and emits first light, a second light emission film which is disposed on the substrate of the second subpixel region and emits second light whose wavelength is shorter than that of the first light, an upper electrode which is disposed on an upper layer side of the first light emission film and the second light emission film and has conductivity, light transmissivity, and light reflectivity at the same time and a cap layer configured to include a high refractive index film, a middle refractive index film, and a low refractive index film whose refractive indices are different from one another on an upper layer side of the upper electrode, and the low refractive index film is disposed to be distant from the substrate more than the other films included in the cap layer are, in the first and second subpixel regions. The middle refractive index film of the first subpixel region is formed to be thicker than the middle refractive index film of the second subpixel region.

In the above-mentioned aspects of the invention, the high refractive index film is disposed to be close to the substrate more than the other films included in the cap layer are.

In the above-mentioned aspects of the invention, the middle refractive index film is disposed to be close to the substrate more than the other films included in the cap layer are.

In the above-mentioned aspects of the invention, the middle refractive index film is formed of Alq3, alpha-NPD, or Liq.

In the above-mentioned aspects of the invention, a microcavity structure is formed so that lights, which are emitted from the first and second light emission films and have wavelengths different from each other, resonate between the cap layer and the upper electrode.

In the above-mentioned aspects of the invention, the organic EL display device further includes a third subpixel region where a third light emission film to emit third light having a wavelength shorter than that of the second light, the upper electrode, and the cap layer are disposed on the substrate. The cap layer in the third subpixel region is configured to include the high refractive index film and the low refractive index film.

### BRIEF DESCRIPTION OF THE DRAWINGS

FIG. 1 is a diagram which schematically shows an organic EL display device according to an embodiment of the present invention.

FIG. 2 is a diagram which schematically shows a display panel.

FIG. 3 is an exemplary diagram which schematically shows a lamination structure of a cross section of the display panel.

FIG. 4A is a diagram which schematically shows respective layers formed between a reflective film and an upper electrode of one pixel.

FIG. 4B is a diagram which schematically shows the respective layers formed between the reflective film and the upper electrode of one pixel.

FIG. 5A is a diagram which schematically shows respective layers of a first subpixel region.

FIG. 5B is a diagram which schematically shows the respective layers of the first subpixel region.

FIG. 5C is a diagram which schematically shows the respective layers of the first subpixel region.

FIG. 6A is a diagram which schematically shows the respective layers of the first subpixel region.

FIG. 6B is a diagram which schematically shows the respective layers of the first subpixel region.

FIG. 6C is a diagram which schematically shows the respective layers of the first subpixel region.

FIG. 7A is a diagram which schematically shows respective layers of a second subpixel region.

FIG. 7B is a diagram which schematically shows the respective layers of the second subpixel region.

FIG. 7C is a diagram which schematically shows the respective layers of the second subpixel region.

FIG. 8A is a diagram which schematically shows the respective layers of the second subpixel region.

FIG. 8B is a diagram which schematically shows the respective layers of the second subpixel region.

FIG. 8C is a diagram which schematically shows the respective layers of the second subpixel region.

### DETAILED DESCRIPTION OF THE INVENTION

Below, each of the one or more embodiments of the present invention is described with reference to the accompanying drawings. Note that the one or more disclosed embodiments are merely examples, and an appropriate variation which a person skilled in the art can easily arrive at without departing from the spirit of the present invention is naturally included in the scope of the present invention. Further, while the width, thickness, shape, and the like of each part in the drawings may be shown schematically as compared with the actual embodiments in order to clarify the description, these are merely examples, and an interpretation of the present invention should not be limited thereto. Furthermore, in the specification and the respective drawings, the same reference symbols may be applied to elements similar to those which have already been shown in another drawing, and a detailed description of such elements may be omitted as appropriate.

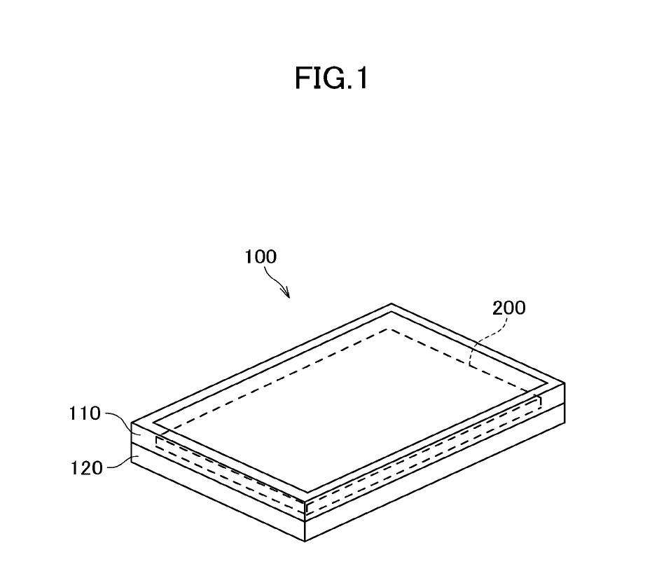

FIG. 1 is a diagram which schematically shows an organic EL display device 100 according to an embodiment of the present invention. As shown in the FIG. 1, the organic EL display device 100 is composed of a display panel 200 which is fixed so as to be sandwiched by an upper frame 110 and a lower frame 120.

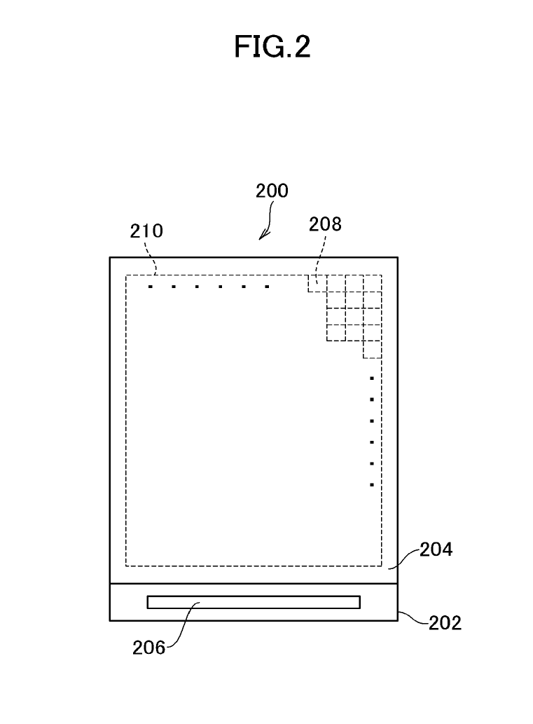

FIG. 2 is a diagram which schematically shows the display panel 200 of FIG. 1. The display panel 200 has an array substrate 202, a protection film 204, and a drive IC (Integrated Circuit) 206.

Further, the display panel 200 has pixels 208 which are arranged in a matrix in a display region 210. Specifically, the display panel 200 has a plurality of pixels each of which has first to third subpixel regions 400, 402, and 404. On each of the first to third subpixel regions 400, 402, and 404, an organic EL layer 314, an upper electrode 316, a cap layer 318, and the like which will be respectively described later are disposed. Organic EL layers 314 disposed on the first to third subpixel regions 400, 402, and 404 respectively emit lights of different wavelengths. Note that the number of subpixel regions which the plurality of pixels have is not limited to be three, and it can be four or more.

On the array substrate 202, an array layer 302, first to third light emission films 412, 414, and 416, a hole transport layer 408, and the like to be described later are formed.

The drive IC 206, for example, applies an electric potential to a drive transistor 304 arranged in each subpixel region for electrically connecting its source and drain, and at the same time sends an electric current corresponding to a gradation value to the respective data signal lines. By the drive IC 206, the display panel 200 displays, on the display region 210, a color image constituted by a plurality of pixels 208 of a plurality of colors.

The protection film 204 is an acrylic film which protects the display panel 200 from an external damage, and is bonded to the array substrate 202 by adhesive.

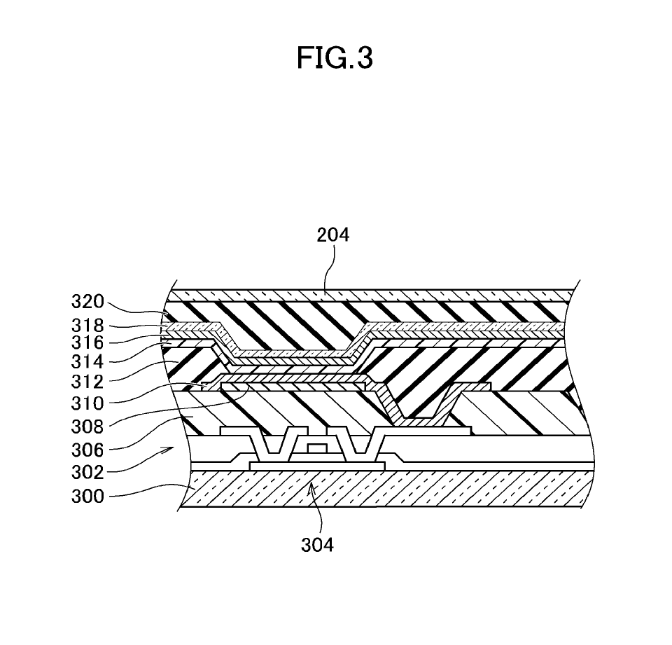

FIG. 3 is a diagram which schematically shows a cross section of the display panel 200. As shown in the FIG. 3, the display panel 200 is configured to include the substrate 300, the array layer 302, the planarizing film 306, the reflection film 308, the lower electrode 310, the rib 312, the organic EL layer 314, the upper electrode 316, the cap layer 318, the sealing film 320, and the protection film 204 in this order, starting from the lower side to the upper side in the FIG. 3.

The substrate 300 is, for example, a glass substrate, but may also be a flexible substrate made of resin.

The array layer 302 is formed on the substrate 300. Specifically, the array layer 302 is formed on the substrate 300 so as to include a plurality of drive transistors 304 which are configured to include a source electrode, a drain electrode, a gate electrode, a semiconductor layer, and the like.

The planarizing film 306 is formed of an insulating material on the array layer 302. Specifically, the planarizing film 306 is formed of an insulating material so as to have a through hole on the upper side of either of the source electrode or the drain electrode of the drive transistor 304, and so as to cover the array layer 302 in a region other than a region where the through hole is formed.

The reflection film 308 is formed, on the planarizing film 306, of a material which reflects light emitted from the organic EL layer 314. Specifically, the reflection film 308 is formed, for example, of Ag.

The lower electrode 310 is formed on the reflection film 308 and the planarizing film 306. Specifically, the lower electrode 310 is formed of a material which is transparent and conductive such as ITO or the like, so as to cover the reflection film 308, and so as to be connected electrically to the source electrode or the drain electrode of the drive transistor 304 via the through hole. It may be configured to form the lower electrode 310 with metal to have the lower electrode 310 function as the reflection film 308 as well. That is, it may be configured that the reflection film 308 is not provided.

The rib 312 is formed on the lower electrode 310. Specifically, the rib 312 is formed such that it covers the planarizing film 306 in a region where the lower electrode 310 is not formed, and that it is formed on the lower electrode 310 in a region where the lower electrode 310 formed. Further, the rib 312 is formed such that it has a rib opening part on the upper layer side of a region where the reflection film 308 is formed. The rib opening part is a region where the light is extracted from the display panel 200.

The organic EL layer 314 is configured to include the first to third light emission films 412, 414, and 416 which emit light, the hole transport layer 408, and the like. Specifically, the first light emission film 412 is disposed on the substrate 300 of the first subpixel region 400, and emits first light. The second light emission film 414 is disposed on the substrate 300 of the second subpixel region 402, and emits second light whose wavelength is shorter than that of the first light. The third light emission film 416 is disposed on the substrate 300 of the third subpixel region 404, and emits third light whose wavelength is shorter than that of the second light. The hole transport layer 408 and the like will be described later.

The upper electrode 316 is formed, on an upper layer side of the first light emission film 412 and the second light emission film 414, of a material which has conductivity, light transmissivity, and light reflectivity. Specifically, the upper electrode 316 is formed so as to cover the organic EL layer 314. The upper electrode 316 is formed of a material which has conductivity as well as light transmissivity and light reflectivity (referred to also as semi-transmitting reflectivity) such as MgAg. The upper electrode 316 supplies electrons to the organic EL layer 314 to thereby have the organic EL layer 314 emit light.

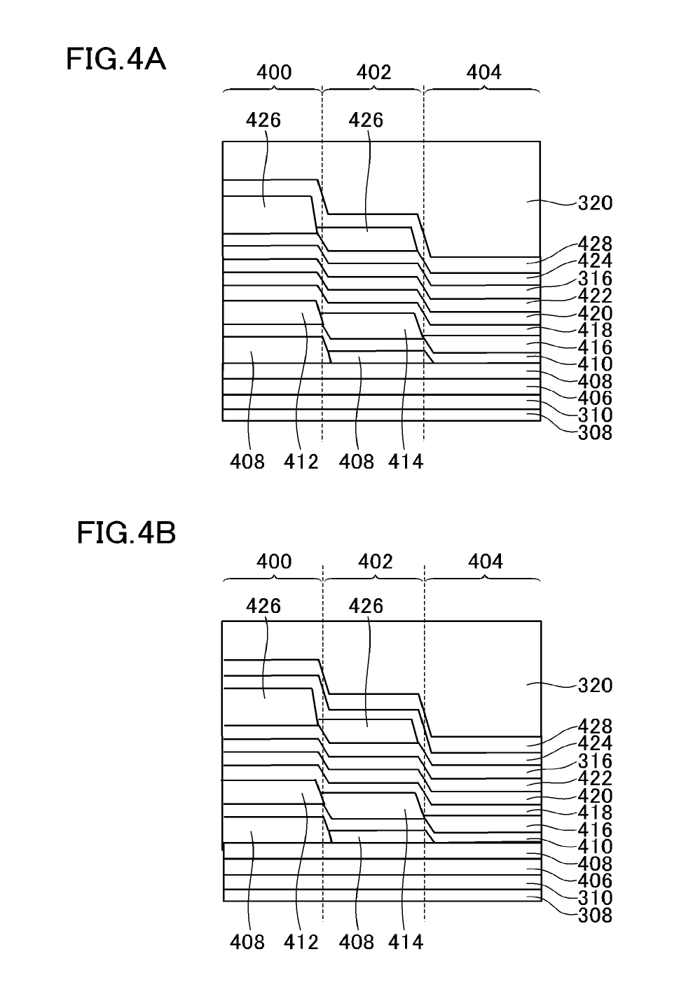

The cap layer 318 is configured to include a high refractive index film 424, a middle refractive index film 426, and a low refractive index film 428 whose refractive indices are different from one another in the first and second subpixel regions 400 and 402, on the upper layer side of the upper electrode 316. The low refractive index film 428 is disposed to be distant from the substrate 300 more than the other films included in the cap layer 318 are. Specifically, the cap layer 318 is, in the first and second subpixel regions 400 and 402, composed of at least three types of layers whose refractive indices are different from one another. The cap layer 318 includes the high refractive index film 424 whose refractive index is high, the low refractive index film 428 whose refractive index is lower than that of the high refractive index film 424, and the middle refractive index film 426 whose refractive index is lower than that of the high refractive index film 424 but is higher than that of the low refractive index film 428. Further, the cap layer 318 is composed of at least two types of layers whose refractive indices are different from each other in the third subpixel region 404. The detailed structure of the cap layer 318 is described with reference to FIG. 4.

The sealing layer 320 is formed on the cap layer 318. Specifically, the sealing layer 320 is formed of an inorganic material which does not allow the permeation of moisture, so as to cover the cap layer 318. The sealing layer 320 prevents deterioration of the organic EL layer 314 due to the permeation of moisture into the organic EL layer 314.

Subsequently, the details of the cap layer 318 is described with reference to FIG. 4A and FIG. 4B. FIG. 4A and FIG. 4B are diagrams which schematically show the respective layers formed between the reflection film 308 and the sealing film 320 in the rib opening part of one pixel 208. As shown in FIG. 4A, at each pixel 208, the reflection film 308, the lower electrode 310, a hole injection layer 406, a hole transport layer 408, an electron block layer 410, the first to third light emission films 412, 414, and 416, a hole block layer 418, an electron transport layer 420, an electron injection layer 422, the upper electrode 316, the high refractive index film 424, the middle refractive index film 426, and the low refractive index film 428, and the sealing film 320 are laminated.

Note that FIG. 4A and FIG. 4B are schematic diagrams, and the reflection film 308 and the lower electrode 310 are illustrated such that they are continuously formed over the first to third subpixel regions 400, 402, and 404, but actually the reflection film 308 and the lower electrode 310 are disposed discontinuously at each of the first to third subpixel regions 400, 402, and 404. Note that FIG. 4A and FIG. 4B schematically show the structure where the first subpixel region 400, the second subpixel region 402, and the third subpixel region 404 are arranged in this order, starting from the left. Further, the hole transport layer 408 and the electron transport layer 420 are also referred to as a charge transport layer. Moreover, the layers from the hole injection layer 406 to the electron injection layer 422 correspond to the organic EL layer 314 in FIG. 3.

The hole injection layer 406 is formed on the lower electrode 310. Specifically, the hole injection layer 406 is formed on the lower electrode 310 in the first to third subpixel regions 400, 402, and 404.

Further, the hole injection layer 406 is formed of a material which has a function of supplying the hole transport layer 408 with holes injected from the lower electrode 310. For example, the hole injection layer 406 is, in order to lower the hole injection barrier, formed of a material having the HOMO level whose energy level gap with respect the Fermi level of the material used for the lower electrode 310 is small.

The hole transport layer 408 is formed to have different thicknesses in the respective first to third subpixel regions 400, 402, and 404. Specifically, the hole transport layer 408 is arranged to have a uniform thickness on the hole injection layer 406, in all of the first to third subpixel regions 400, 402, and 404. Further, an additional hole transport layer 408 is, in the first and second subpixel regions 400 and 402, further disposed on the hole transport layer 408 described as above.

Here, the hole transport layer 408 disposed on the first subpixel region 400 is formed to be thicker than the hole transport layer 408 disposed on the second subpixel region 402. By this configuration, distances between the reflection film 308 and the first to third light emission films 412, 414, and 416 are, in the first to third subpixel regions 400, 402, and 404 respectively, lengths with which the lights emitted by the first to third light emission films 412, 414, and 416 resonate. By this configuration, the microcavity structure is formed between the reflection film 308 and the first to third light emission films 412, 414, and 416.

Further, the hole transport layer 408 is formed of a material having a function to supply the first to third light emission films 412, 414, and 416 with the holes supplied by the hole injection layer 406. For example, it is preferable to form the hole transport layer 408 with a material having a HOMO level whose energy level gap with respect to a HOMO level of the hole injection layer 406 is small.

The electron block layer 410 is formed on the hole transport layer 408. Specifically, the hole block layer 418 is formed, in the first to third subpixel regions 400, 402, and 404, of a material having a function to prevent the electrons supplied to the first to third light emission films 412, 414, and 416 by the electron transport layer 420 from reaching the hole transport layer 408.

The first light emission film 412 is disposed on the electron block layer 410 in the first subpixel region 400. The first light emission film 412 is formed of a material which emits, for example, red light.

The second light emission film 414 is disposed on the electron block layer 410 in the second subpixel region 402. The second light emission film 414 is formed of a material which emits, for example, green light.

The third light emission film 416 is disposed on the electron block layer 410 in the third subpixel region 404. The third light emission film 416 is formed of a material which emits, for example, blue light.

The hole block layer 418 is formed on the first to third light emission films 412, 414, and 416. Specifically, the hole block layer 418 is formed, on the first to third light emission films 412, 414, and 416, of a material having a function to prevent the holes supplied to the first to third light emission films 412, 414, and 416 by the hole transport layer 408 from reaching the electron transport layer 420.

The electron transport layer 420 is formed on the hole block layer 418. Specifically, the electron transport layer 420 is formed, on the hole block layer 418, of a material having a function to supply the first to third light emission films 412, 414, and 416 with the electrons supplied by the upper electrode 316.

The electron injection layer 422 is formed on the electron transport layer 420. Specifically, in the first to third subpixel regions 400, 402, and 404, the electron injection layer 422 is formed on the electron transport layer 420. Further, the electron injection layer 422 is formed of a material having a function to supply the electron transport layer 420 with the electrons injected from the upper electrode 316.

The high refractive index film 424 is disposed on the upper electrode 316. Specifically, as shown in FIG. 4A, the high refractive index film 424 is disposed close to the substrate 300 more than the other films included in the cap layer 318 are. The high refractive index film 424 is formed of a material having a refractive index higher than those of the low refractive index film 428 and the middle refractive index film 426.

The middle refractive index film 426 is disposed on the high refractive index film 424. Specifically, the middle refractive index film 426 is formed on the high refractive index film 424 of the first subpixel region 400 and the second subpixel region 402. Further, the middle refractive index film 426 of the first subpixel region 400 is formed to be thicker than the middle refractive index film 426 of the second subpixel region 402.

The low refractive index film 428 is disposed on the middle refractive index film 426 and the high refractive index film 424. Specifically, the low refractive index film 428 is disposed on the middle refractive index film 426 in the first and second subpixel regions 400 and 402. Further, the low refractive index film 428 is disposed on the high refractive index film 424 in the third subpixel region 404.

As has been described above, the cap layer 318 is constituted by the high refractive index film 424, the middle refractive index film 426, and the low refractive index film 428. The cap layer 318 in the first and second subpixel regions 400 and 402 is configured to include the high refractive index film 424, the middle refractive index film 426, and the low refractive index film 428. The cap layer 318 in the third subpixel region 404 is configured to include the high refractive index film 424, and the low refractive index film 428.

By the configuration of the cap layer 318 as described above, the microcavity structure is formed so that the lights of different wavelengths emitted from the first and second light emission films 412 and 414 resonates between the cap layer 318 and the upper electrode 316. Specifically, the lights emitted from the first to third light emission films 412, 414, and 416 are reflected at an interface between layers with different refractive indices. Therefore, the lights are reflected at the interface between the high refractive index film 424 and the middle refractive index film 426 and the interface between the middle refractive index film 426 and the low refractive index film 428 (hereinafter referred to as the interfaces inside the cap layer 318).

As has been described above, the middle refractive index film 426 is formed with different thicknesses in the first and second subpixel regions 400 and 402 respectively, in accordance with the wavelengths of lights emitted from the first and second light emission films 412 and 414. Further, in the third subpixel region 404, the middle refractive index film 426 is not disposed. By this configuration, the distances between the upper electrode 316 and the interfaces inside the cap layer 318 become the lengths with which the lights emitted by the first to third light emission films 412, 414, and 416 resonate in the first to third subpixel regions 400, 402, and 404, respectively. Therefore, the microcavity structure is formed between the upper electrode 316 and the interfaces inside the cap layer 318.

Here, in order that the microcavity structure may be formed, the optical path lengths between the upper electrode 316 and the interfaces inside the cap layer 318 in the first to third subpixel regions 400, 402, and 404 need to be integral multiples of the wavelengths of the lights emitted from the first to third light emission films 412, 414, and 416, respectively. In the case where the optical path lengths are adjusted by controlling the thickness of the high refractive index film 424, even a slight change in the thickness of the high refractive index film 424 greatly changes the optical path lengths. Meanwhile, in the case where the optical path lengths are adjusted by controlling the thickness of the medium refractive index film 426, the change in the optical path lengths due to the thickness change can be reduced as compared with the case where the adjustment is performed by controlling the thickness of the high refractive index film 424. By this configuration, the adjustment of the optical path lengths can be made more easily.

Note that the middle refractive index film 426 may be arranged close to the substrate 300 more than the other films included in the cap layer 318 are. Specifically, as shown in FIG. 4B, the middle refractive index film 426 may be disposed on the upper electrode 316 in the first and second subpixel regions 400 and 402. In this case, the high refractive index film 424 is disposed on the middle refractive index film 426 in the first and second subpixel regions 400 and 402. Further, the high refractive index film 424 is disposed on the upper electrode 316 in the third subpixel region 404. Moreover, the low refractive index film 428 is disposed on the high refractive index film 424. Even in this configuration, the microcavity structure can be formed between the upper electrode 316 and the interfaces inside the cap layer 318, as in the configuration as shown in FIG. 4A.

Further, the middle refractive index film 426 may be disposed also in the third subpixel region 404. In this case, the middle refractive index film 426 of the third subpixel region 404 is formed to be thinner than the middle refractive index film 426 of the second subpixel region 402, in accordance with the wavelength of light emitted from the third light emission film 416. Even in such a configuration, the microcavity structure can be formed between the upper electrode 316 and the interfaces inside the cap layer 318, as in the above cases.

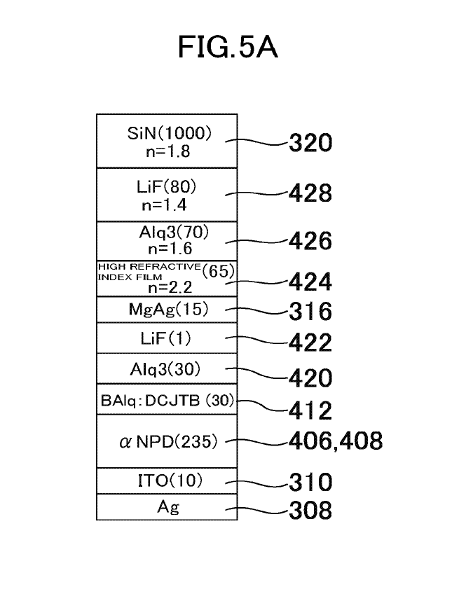

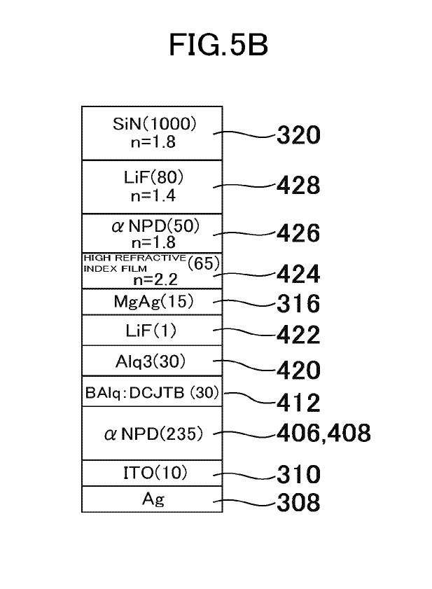

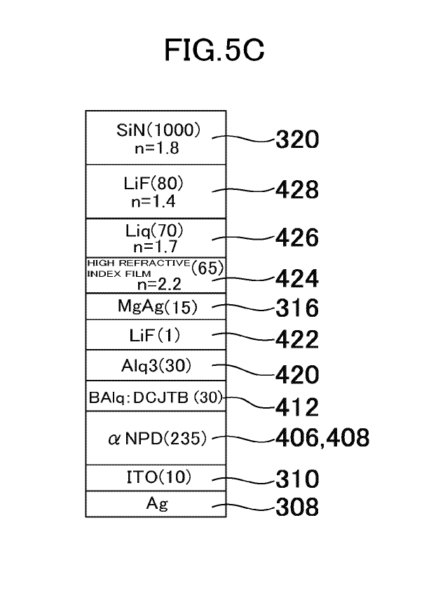

Subsequently, specific materials and thicknesses of the respective layers configured as shown in FIG. 4A are described. FIGS. 5A to 5C are schematic diagrams which show the configurations of the reflection film 308 to the sealing film 320 in the first subpixel region 400.

As shown in FIG. 5A, the lower electrode 310 is formed of ITO (Indium Tin Oxide) to be as thick as 10 nm. The hole injection layer 406 and the hole transport layer 408 are formed of naphthyl-substituted benzidine (alpha-NPD) to be as thick as 235 nm. As to the first light emission film 412, the host is Bis(2-methyl-8-quinolinolato)-4-(phenylphenolato)aluminum (BAlq), the light emission dopant is DCJTB (4-(Dicyanomethylene)-2-tert-butyl-6-(1,1,7,7-tetramethyljulolidin-4-yl-vinyl)-4H-pyran, 4-(dicyanomethylene)-2-tert-butyl-6-(1,1,7,7-tetramethyljulolidin-4-yl-vinyl)-4H-pyran), and the thickness of the first light emission film 412 is formed to be as thick as 30 nm. The electron transport layer 420 is formed of (Tris(8-hydroxyquinolinato)aluminum (Alq3) to be as thick as 30 nm. The electron injection layer 422 is formed of lithium fluoride (LiF) to be as thick as 1 nm. The upper electrode 316 is formed of magnesium silver (MgAg) to be as thick as 15 nm. The high refractive index film 424 is formed of an organic material whose refractive index is 2.2 to be as thick as 65 nm. The middle refractive index film 426 is formed of Alq3 to be as thick as 70 nm. Note that the refractive index of Alq3 is 1.6. The low refractive index film 428 is formed of LiF to be as thick as 80 nm. Note that the refractive index of LiF is 1.4. The sealing film 320 is formed of silicon nitride (SiN) to be as thick as 1000 nm. Note that the refractive index of SiN is 1.8.

The inventor examined the light emitted from the first subpixel region 400 having the configuration as shown in FIG. 5A, and confirmed that they could obtain chromaticity and luminance the same as the ones which they would obtain if they replace the middle refractive index film 426 with the high refractive index film 424. Specifically, they examined, as the comparison target, the configuration as shown in FIG. 5A which had, instead of the high refractive index film 424 and the middle refractive index film 426 as shown in the figure, the high refractive index film 424 formed of an organic material with a refractive index of 2.2 and a thickness of 125 nm. As a result, in the configuration of the comparison target, the chromaticity of the light emitted from the first subpixel region 400 was (0.680, 0.315) in an xyz color system. Further, the luminance of the light was 19.9 cd/A. Meanwhile, the chromaticity of the light emitted from the first subpixel region 400 having the configuration as shown in FIG. 5A was (0.680, 0.315). Further, the luminance of the light was 19.7 cd/A. Thus, it has been found that by the configuration having the middle refractive index film 426, the chromaticity and the luminance the same as those of the configuration of the comparison target can be obtained.

Further, according to the embodiment as shown in FIG. 5A as above, the usage amount of the material of the high refractive index film 424 can reduced as compared with the case of the configuration of the comparison target. The material having the high refractive index is expensive as compared with the material having the middle refractive index, and therefore the manufacturing cost of the organic EL display device 100 can be reduced.

Note that the middle refractive index film 426 may be formed of alpha-NPD. Specifically, as shown in FIG. 5B, the middle refractive index film 426 may be formed of alpha-NPD to be as thick as 50 nm. Note that the refractive index of alpha-NPD is 1.8. The chromaticity of the light emitted from the first subpixel region 400 having the configuration as shown in FIG. 5B was (0.680, 0.315). Further, the luminance of the light was 20.3 cd/A.

Further, the middle refractive index film 426 may be formed of 8-Hydroxyquinolinolato-lithium (Liq). Specifically, as shown in FIG. 5C, the middle refractive index film 426 may be formed of Liq to be as thick as 70 nm. Note that the refractive index of Liq is 1.7. The chromaticity of the light emitted from the first subpixel region 400 having the configuration as shown in FIG. 5C was (0.680, 0.315). Further, the luminance of the light was 19.8 cd/A. Thus, it has been found that by the configurations as shown in FIG. 5B and FIG. 5C, the chromaticity and the luminance the same as those of the configuration of the comparison target can be obtained.

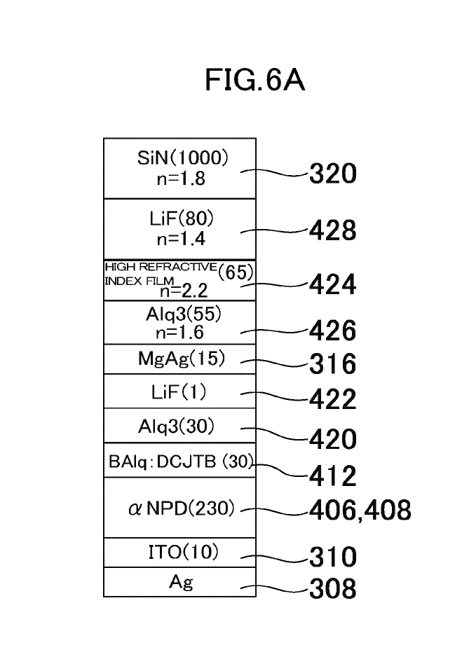

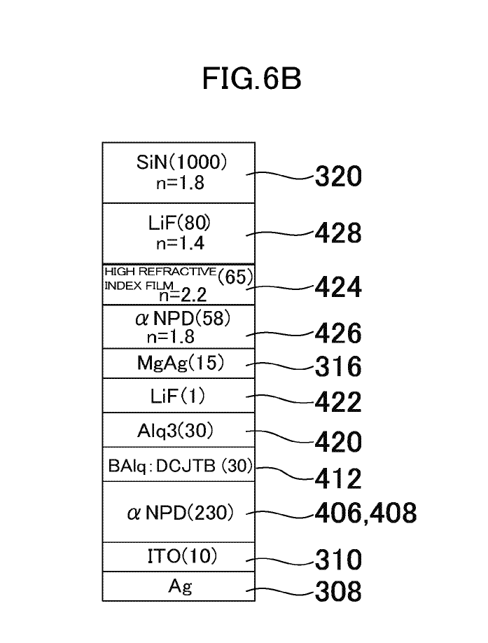

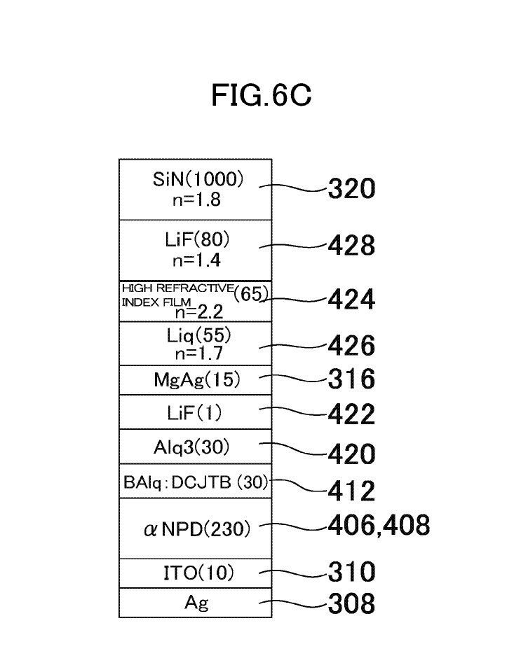

Subsequently, as to the embodiment having the configuration as shown in FIG. 4B, specific materials and thicknesses of the respective layers are described. The embodiments having the configurations as shown in FIGS. 6A to 6C are the same as the embodiments as shown in FIGS. 5A to 5C, except for the configuration of the middle refractive index film 426 and the high refractive index film 424.

In the configuration as shown in FIG. 6A, the middle refractive index film 426 is formed of Alq3 to be as thick as 55 nm on the upper electrode 316. The high refractive index film 424 is formed of an organic material whose refractive index is 2.2 to be as thick as 65 nm on the middle refractive index film 426. The chromaticity of the light emitted from the first subpixel region 400 having this configuration was (0.680, 0.316). Further, the luminance of the light was 20.2 cd/A.

In the configuration as shown in FIG. 6B, the middle refractive index film 426 is formed of alpha-NPD to be as thick as 58 nm on the upper electrode 316. The high refractive index film 424 is formed of an organic material whose refractive index is 2.2 to be as thick as 65 nm on the middle refractive index film 426. The chromaticity of the light emitted from the first subpixel region 400 having this configuration was (0.680, 0.316). Further, the luminance of the light was 20.1 cd/A.

In the configuration as shown in FIG. 6C, the middle refractive index film 426 is formed of Liq to be as thick as 55 nm on the upper electrode 316. The high refractive index film 424 is formed of an organic material whose refractive index is 2.2 to be as thick as 65 nm on the middle refractive index film 426. The chromaticity of the light emitted from the first subpixel region 400 having this configuration was (0.680, 0.316). Further, the luminance of the light was 20.2 cd/A. Thus, it has been found that by the configurations as shown in FIG. 6B and FIG. 6C, the chromaticity and the luminance the same as those of the configurations of the comparison targets can be obtained.

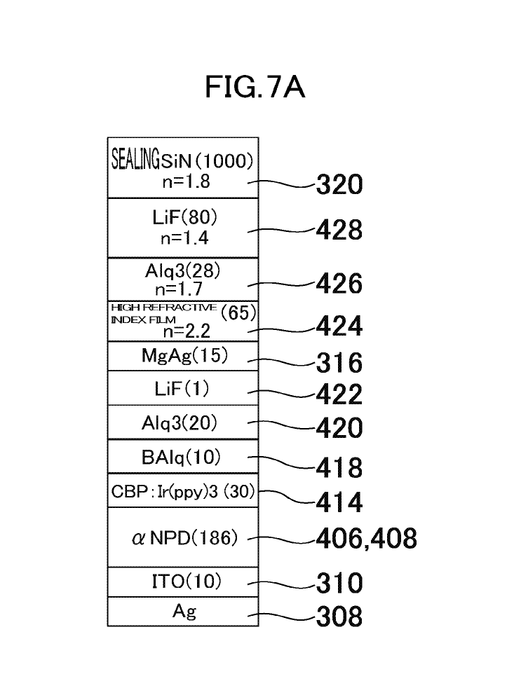

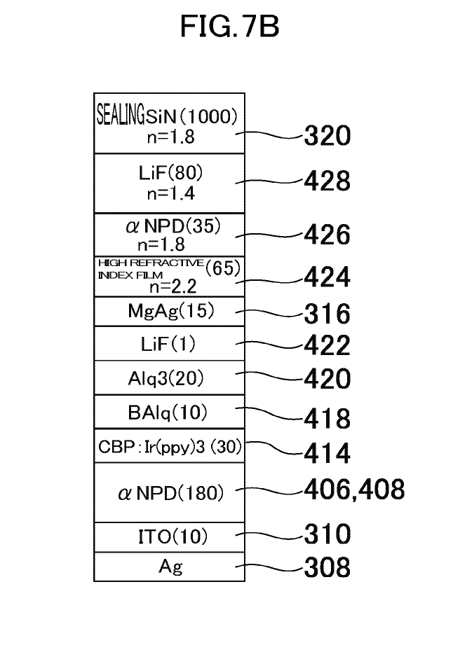

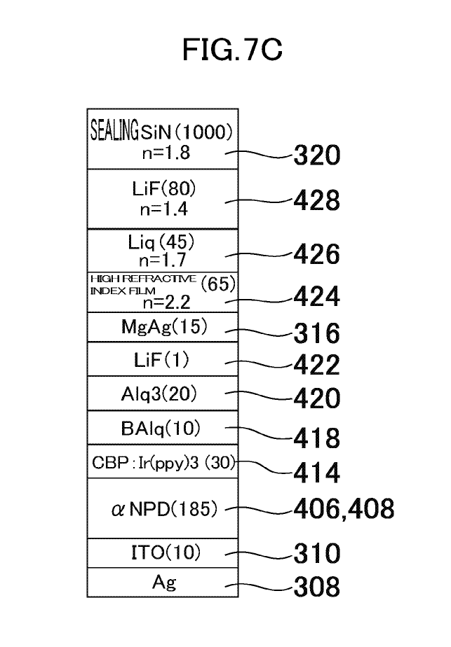

FIGS. 7A to 7C are schematic diagrams which show the configuration of the reflection film 308 to the sealing film 320 in the second subpixel region 402.

As shown in FIG. 7A, the lower electrode 310 is formed of ITO (Indium Tin Oxide) to be as thick as 10 nm. The hole injection layer 406 and the hole transport layer 408 are formed of alpha-NPD to be as thick as 186 nm. As to the second light emission film 414, the host is 4,4′-Bis(carbazol-9-yl)biphenyl (CBP), the light emission dopant is Ir(ppy)3(Tris[2-phenylpyridinato-C2,N]iridium (III)), and the thickness of the second light emission film 414 is formed to be as thick as 30 nm. The hole block layer 418 is formed of BAlq to be as thick as 10 nm. The electron transport layer 420 is formed of Alq3 to be as thick as 20 nm. The electron injection layer 422 is formed of lithium fluoride (LiF) to be as thick as 1 nm. The upper electrode 316 is formed of magnesium silver (MgAg) to be as thick as 15 nm. The high refractive index film 424 is formed of an organic material whose refractive index is 2.2 to be as thick as 65 nm. The middle refractive index film 426 is formed of Alq3 to be as thick as 28 nm. The low refractive index film 428 is formed of LiF to be as thick as 80 nm. The sealing film 320 is formed of silicon nitride (SiN) to be as thick as 1000 nm.

In the second subpixel region 402, as in the first subpixel region 400, the middle refractive index film 426 may be formed of alpha-NPD or Liq. Specifically, as shown in FIG. 7B, the middle refractive index film 426 may be formed of alpha-NPD to be as thick as 35 nm. Further, as shown in FIG. 7C, the middle refractive index film 426 may be formed of Liq to be as thick as 45 nm. Note that the thicknesses of the hole injection layers 406 and the hole transport layers 408 as shown in FIG. 7B and FIG. 7C are different from those of the hole injection layer 406 and the hole transport layer 408 as shown in FIG. 7A, but those thicknesses are matters to be designed as appropriate.

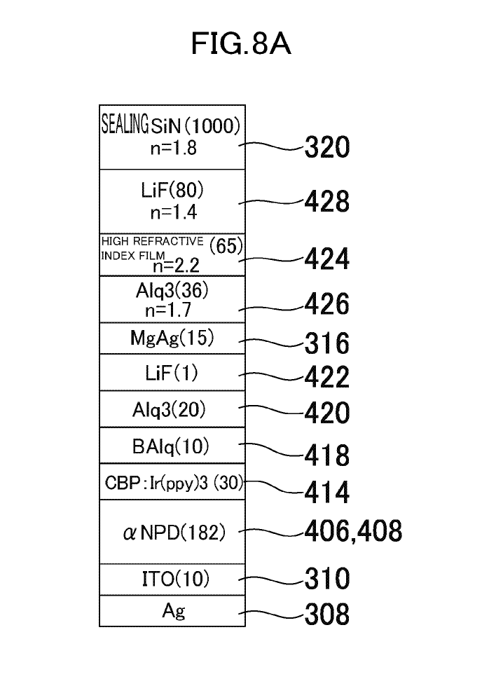

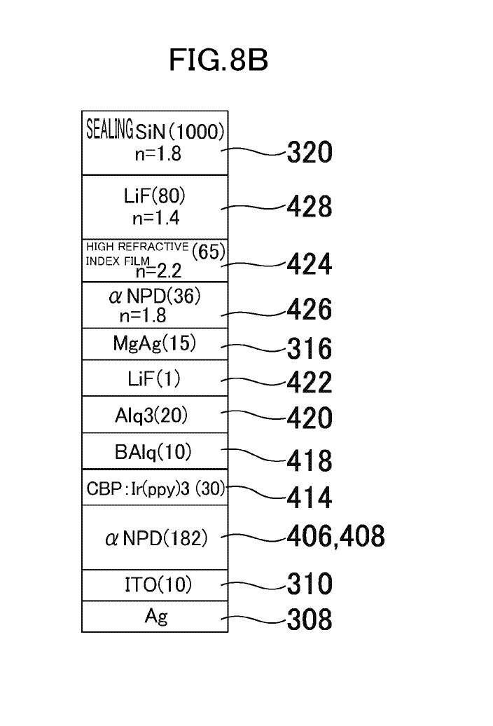

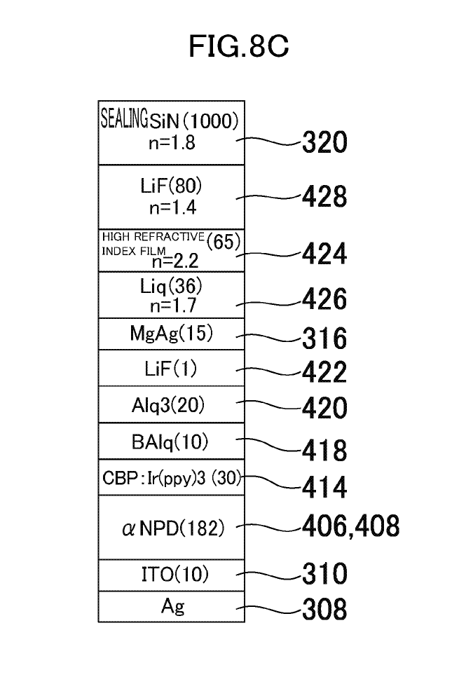

Subsequently, specific materials and thicknesses of the respective layers (as shown in FIG. 4B) in the second subpixel region 402 are described. The embodiments having the configurations as shown in FIGS. 8A to 8C are the same as the embodiments as shown in FIGS. 7A to 7C, except for the configuration of the hole transport layer 408, the hole injection layer 406, the middle refractive index film 426, and the high refractive index film 424. Note that the hole injection layer 406 and the hole transport layer 408 are different from each other in their thicknesses, but are the same as each other in that they are formed of alpha-NPD.

In the configuration as shown in FIG. 8A, the middle refractive index film 426 is formed of Alq3 to be as thick as 36 nm on the upper electrode 316. The high refractive index film 424 is formed of an organic material whose refractive index is 2.2 to be as thick as 65 nm on the middle refractive index film 426.

In the configuration as shown in FIG. 8B, the middle refractive index film 426 is formed of alpha-NPD to be as thick as 36 nm on the upper electrode 316. The high refractive index film 424 is formed of an organic material whose refractive index is 2.2 to be as thick as 65 nm on the middle refractive index film 426.

In the configuration as shown in FIG. 8C, the middle refractive index film 426 is formed of Liq to be as thick as 36 nm on the upper electrode 316. The high refractive index film 424 is formed of an organic material whose refractive index is 2.2 to be as thick as 65 nm on the middle refractive index film 426.

As in the configurations as described above, the middle refractive index film 426 disposed in the second subpixel region 402 is formed to be as thick as approximately one third to two thirds of the thickness of the middle refractive index film 426 disposed in the first subpixel region 400. Also in this configuration, as the cases described above, the microcavity structure can be formed between the upper electrode 316 and the interfaces inside the cap layer 318. By this configuration, also in the second subpixel region 402, the chromaticity and the luminance similar to those of the configuration not to have the middle refractive index film 426 can be obtained.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An organic EL display device having a first subpixel region and a second subpixel region, comprising:
a substrate;
a first light emission film which is disposed on the substrate of the first subpixel region and emits first light;
a second light emission film which is disposed on the substrate of the second subpixel region and emits second light whose wavelength is shorter than that of the first light;
an upper electrode which is disposed on an upper layer side of the first light emission film and the second light emission film and has conductivity, light transmissivity, and light reflectivity at the same time; and
a cap layer configured to include a high refractive index film, a middle refractive index film, and a low refractive index film whose refractive indices are different from one another on an upper layer side of the upper electrode, and the low refractive index film is disposed to be distant from the substrate more than the other films included in the cap layer are, in the first and second subpixel regions, wherein
the middle refractive index film of the first subpixel region is formed to be thicker than the middle refractive index film of the second subpixel region.

2. The organic EL display device according to claim 1, wherein
the high refractive index film is disposed to be close to the substrate more than the other films included in the cap layer are.

3. The organic EL display device according to claim 1, wherein
the middle refractive index film is disposed to be close to the substrate more than the other films included in the cap layer are.

4. The organic EL display device according to claim 1, wherein
the middle refractive index film is formed of Alq3, alpha-NPD, or Liq.

5. The organic EL display device according to claim 1, wherein
a microcavity structure is formed so that lights, which are emitted from the first and second light emission films and have wavelengths different from each other, resonate between the cap layer and the upper electrode.

6. The organic EL display device according to claim 1, further comprising a third subpixel region where a third light emission film to emit third light having a wavelength shorter than that of the second light, the upper electrode, and the cap layer are disposed on the substrate, wherein
the cap layer in the third subpixel region is configured to include the high refractive index film and the low refractive index film.
